(19) United States
(12) Patent Application Publication
(10) Pub. No.: US 2026/0079179 A1
(43) Pub. Date: Mar. 19, 2026

(54) PROBE

(71) Applicant: KABUSHIKI KAISHA NIHON MICRONICS, Tokyo (JP)

(72) Inventors: Toshinaga Takeya, Aomori (JP); Yasutaka Kishi, Aomori (JP)

(73) Assignee: KABUSHIKI KAISHA NIHON MICRONICS, Tokyo (JP)

(21) Appl. No.: 19/398,492

(22) Filed: Nov. 24, 2025

Related U.S. Application Data
(63) Continuation of application No. PCT/JP2024/019035, filed on May 23, 2024.

(30) Foreign Application Priority Data
Jun. 1, 2023 (JP) 2023-090723

(51) Int. Cl. G01R 1/067

(52) U.S. Cl. CPC G01R 1/06738

(57) ABSTRACT

A probe includes: a foot portion having an elongated shape; a flat plate-shaped support member that is coupled to one end of the foot portion, extends in a first direction, and has a first plate thickness; an arm member that has one end coupled to the support member and extends in a longitudinal direction of the foot portion; a flat plate-shaped tip member that is coupled to the other end of the arm member, extends in the first direction, and has the first plate thickness; and a contact portion that projects from the tip member in the first direction. A projection having a width narrower than the first plate thickness in the first direction is formed on an outer edge portion of the support member and an outer edge portion of the tip member.

### CROSS-REFERENCE TO RELATED APPLICATIONS

The present application is a continuation of International Application No. PCT/JP2024?019035 filed on May 23, 2024 and based upon and claims the benefit of priority from Japanese Patent Application No 2023-090723 filed on June 01 2023 the entire contents of which incorporated herein by reference.

### TECHNICAL FIELD

The present disclosure relates to a probe for use in an electrical connection apparatus.

### BACKGROUND ART

An electrical connection apparatus having a probe that comes into contact with an inspected object is used for inspection of inspected objects such as integrated circuits. In inspection using the electrical connection apparatus, one end portion of the probe is brought into contact with an electrode terminal of the inspected object. The other end portion of the probe is electrically connected to a connection terminal arranged on a circuit substrate of the electrical connection apparatus. The connection terminal is electrically connected to an inspection device such as a tester. Signals can be transmitted and received between the inspected object and the inspection device via the probe.

The probe is housed in a predetermined position using a fixing jig for fixing the probe. The fixing jig includes a first guide plate and a second guide plate, each having a flat plate shape with a rectangular opening formed therein.

The first guide plate and the second guide plate are stacked and arranged such that the openings coincide with each other in the initial state. The size of the openings is slightly larger than the cross section of the probe.

Therefore, the probe can be easily inserted into the opening in the initial state.

After the probe is inserted into the opening, the first guide plate is slid in the plane direction. More specifically, the first guide plate is slid by a slight distance in the long side direction and the short side direction of the rectangular opening. The four surfaces of the probe are restrained by the inner surface of each opening, thereby enabling the probe to be fixed at a desired position.

### SUMMARY

However, in the openings formed in the first guide plate and the second guide plate, the corner portions are not formed at right angles but are formed in an arc shape. That is, during the manufacture of each guide plate, it is difficult to form the corner portions of the opening portions at right angles and they are inevitably formed in an arc shape.

Therefore, when the first guide plate is slid, there has been a problem that it is difficult to accurately contact and constrain the four surfaces of the probe to the inner surface of each opening, and the probe cannot be accurately positioned.

The present disclosure has been made in view of the above problem, and an object of the present disclosure is to provide a probe that can be accurately positioned even when a guide plate provided with an opening having an arc-shaped corner portion is used.

A probe according to an aspect of the present disclosure includes: a foot portion having an elongated shape; a flat plate-shaped support member that is coupled to one end of the foot portion, extends in a first direction, and has a first plate thickness; an arm member that has one end coupled to the support member and extends in a longitudinal direction of the foot portion; a flat plate-shaped tip member that is coupled to the other end of the arm member, extends in the first direction, and has the first plate thickness; and a contact portion that projects from the tip member in the first direction, in which a projection having a width narrower than the first plate thickness in the first direction is formed on an outer edge portion of the support member and an outer edge portion of the tip member.

The present disclosure enables a probe to be accurately positioned even when a guide plate provided with an opening having an arc-shaped corner portion is used.

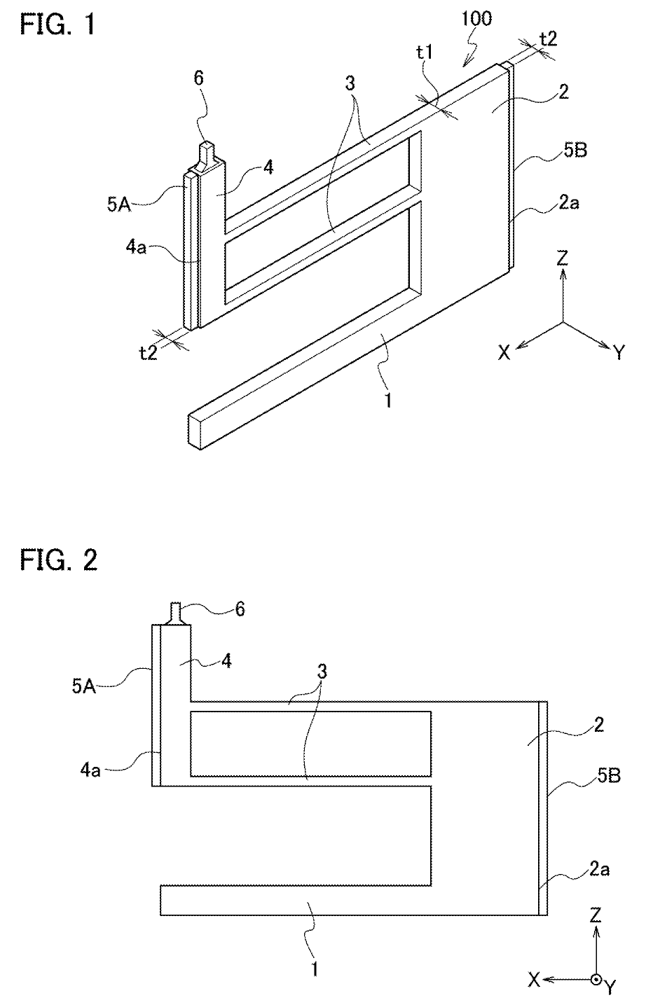

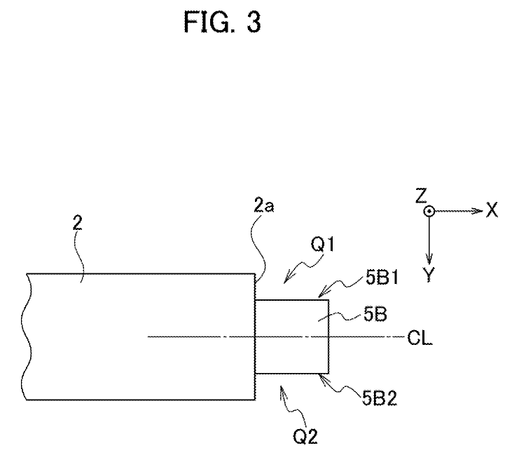

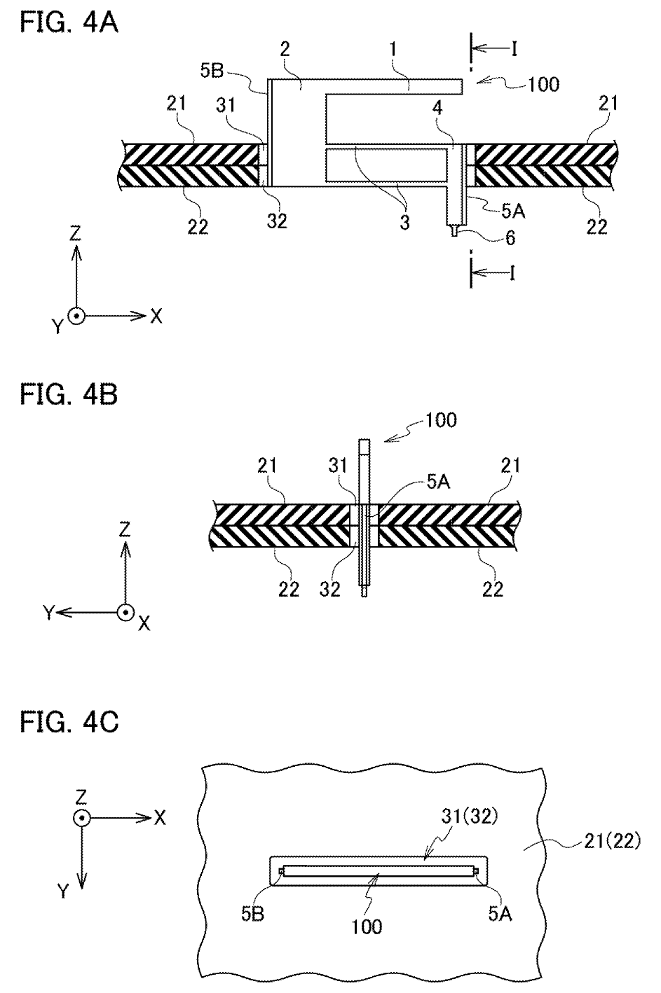

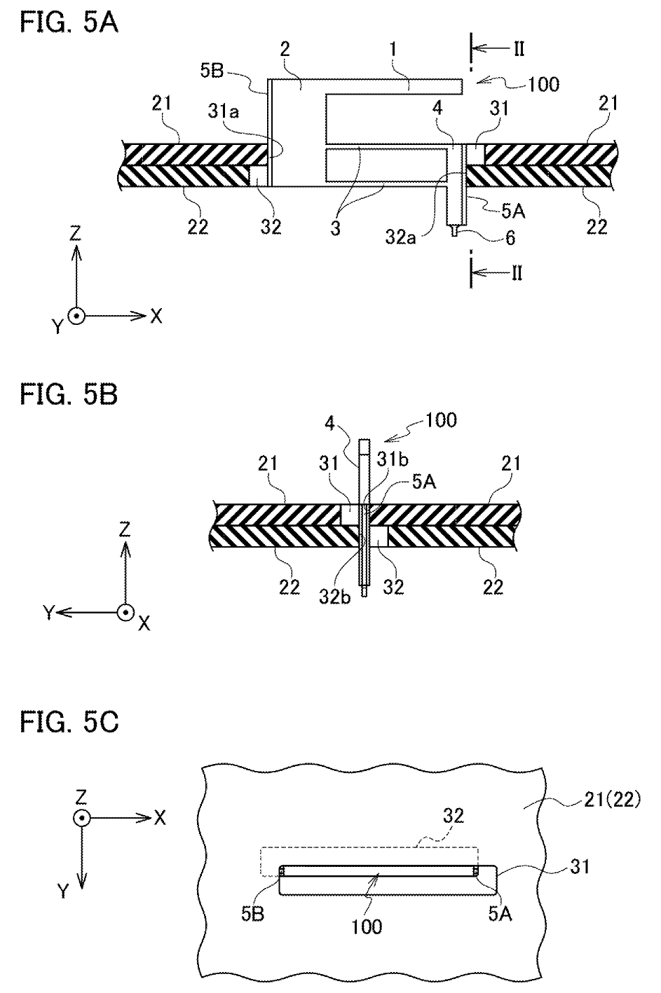

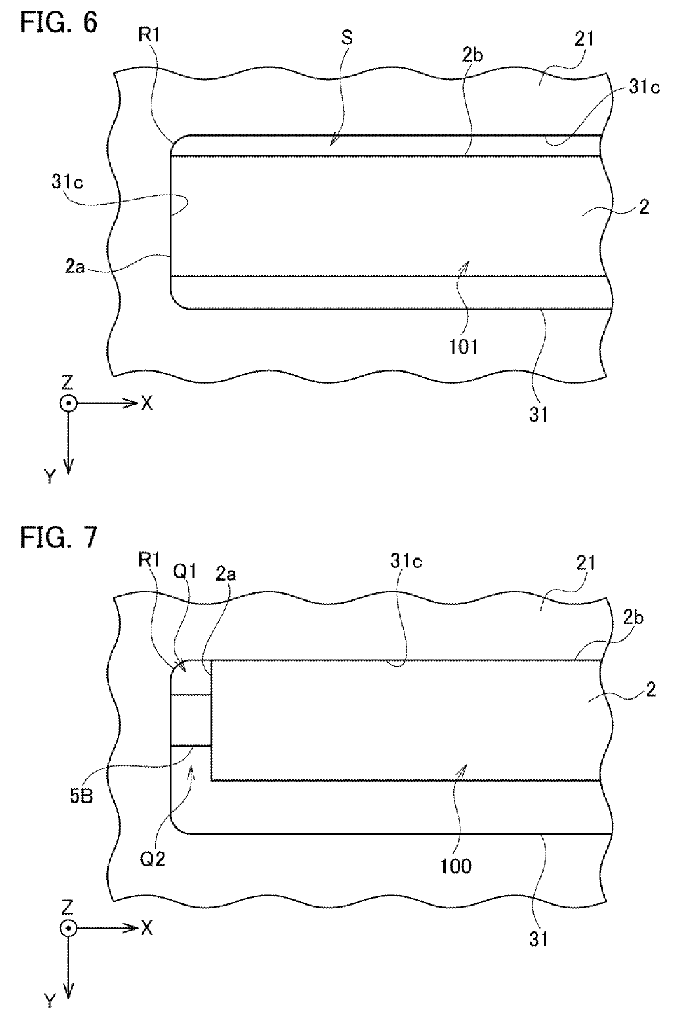

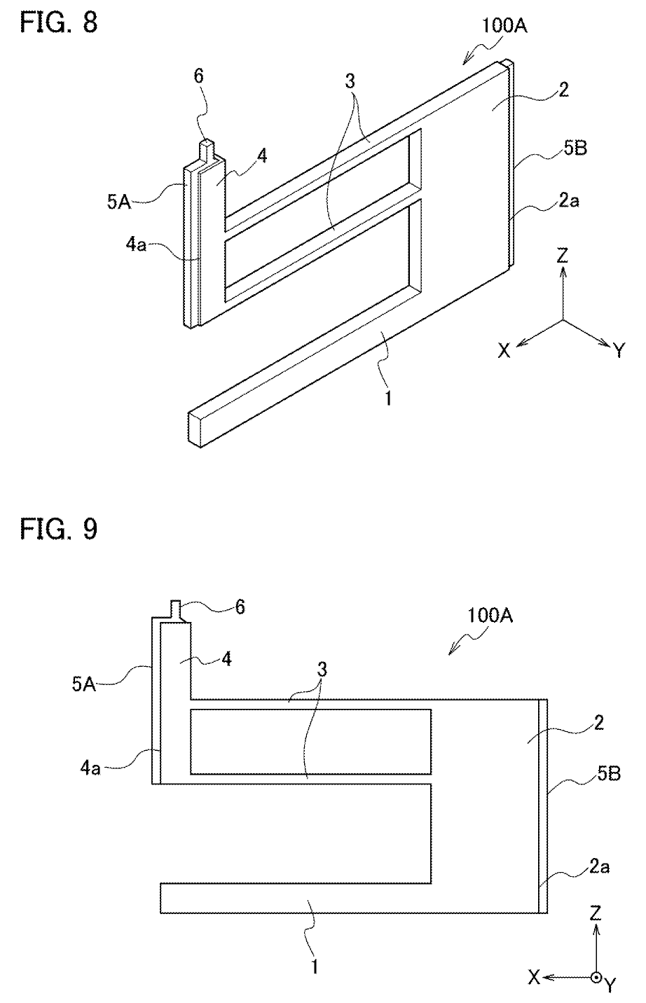

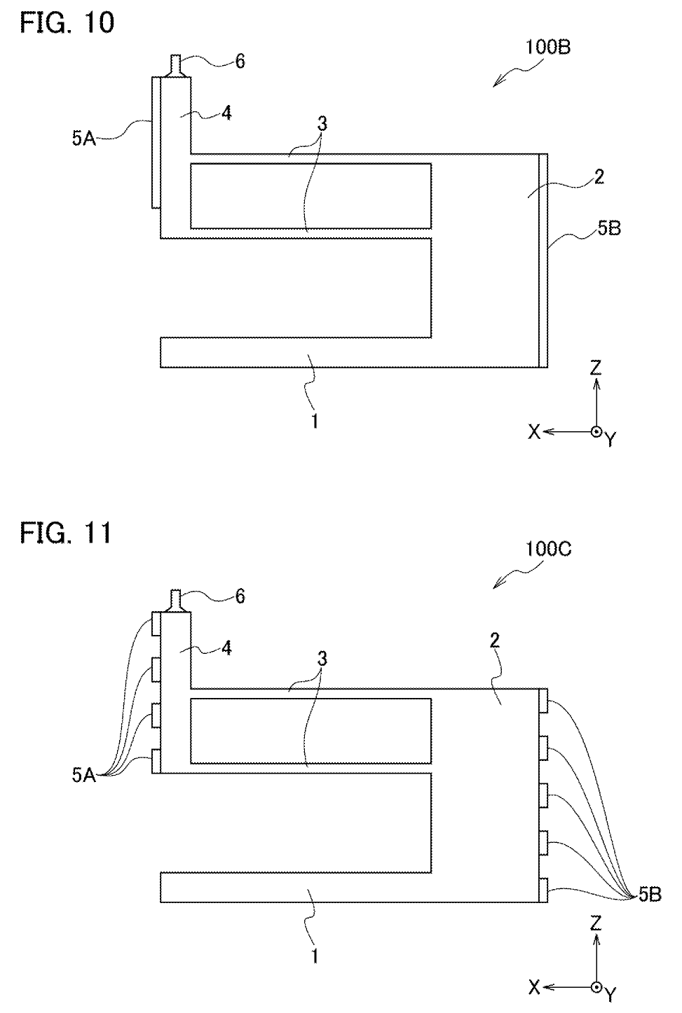

### BRIEF DESCRIPTION OF DRAWINGS

[FIG. 1] FIG. 1 is a perspective view of a probe according to a first embodiment.

[FIG. 2] FIG. 2 is a side view of the probe according to the first embodiment.

[FIG. 3] FIG. 3 is an explanatory view illustrating a positional relationship between an outer edge portion of a support member and a projection.

[FIG. 4A] FIG. 4A is a front view schematically illustrating the probe inserted into openings formed in two guide plates of a fixing jig.

[FIG. 4B] FIG. 4B is a side view illustrating the probe inserted into the openings formed in two guide plates of the fixing jig.

[FIG. 4C] FIG. 4C is a plan view illustrating the probe inserted into the openings formed in two guide plates of the fixing jig.

[FIG. 5A] FIG. 5A is a front view schematically illustrating the state of the probe in the opening when the first guide plate is slid.

[FIG. 5B] FIG. 5B is a side view schematically illustrating the state of the probe in the opening when the first guide plate is slid.

[FIG. 5C] FIG. 5C is a plan view schematically illustrating the state of the probe in the opening when the first guide plate is slid.

[FIG. 6] FIG. 6 is an explanatory view illustrating in detail a positional relationship between the support member and the opening when a probe according to a comparative example is used.

[FIG. 7] FIG. 7 is an explanatory view illustrating in detail a positional relationship between the support member and the opening when the probe according to the embodiment is used.

[FIG. 8] FIG. 8 is a perspective view of a probe according to a first modified example.

[FIG. 9] FIG. 9 is a side view of the probe according to the first modified example.

[FIG. 10] FIG. 10 is a side view of a probe according to a second modified example.

[FIG. 11] FIG. 11 is a side view of a probe according to a third modified example.

### DESCRIPTION OF EMBODIMENTS

Embodiments of the present disclosure will be described below with reference to the drawings. The same or similar elements illustrated in the figures are denoted by the same or similar reference numerals. However, the drawings are illustrated schematically, and it should be noted that the proportions of the thicknesses or lengths of the respective parts and the like are not drawn to scale. It should also be understood that the relationships or proportions of the dimensions between the respective drawings are different from each other in some elements. The embodiments described below exemplify a device and a method for embodying the technical idea of the present disclosure. In the embodiments of the present disclosure, the material, shape, structure, arrangement, and the like of the components are not limited to the following description.

### First embodiment

FIG. 1 is a perspective view illustrating the configuration of a probe according to a first embodiment of the present disclosure, and FIG. 2 is a side view of the probe. As illustrated in FIGS. 1 and 2, a probe 100 according to the first embodiment includes a foot portion 1, a support member 2, two arm members 3, and a tip member 4. In FIGS. 1 and 2, the longitudinal direction of the foot portion 1 is defined as the X-axis direction, the thickness direction of the probe 100 is defined as the Y-axis direction, and the direction orthogonal to the X-Y plane is defined as the Z-axis direction.

The probe 100 is entirely formed of a conductive plate having a thickness t1 (first plate thickness). The material of the probe 100 is, for example, a Ni-B (nickel-boron) alloy.

As illustrated in FIGS. 1 and 2, the foot portion 1 has an elongated shape extending in the X-axis direction, and one end of the support member 2 extending in the Z-axis direction orthogonal to the longitudinal direction of the foot portion 1 is coupled to one end of the foot portion 1. That is, the Z-axis direction corresponds to a first direction in which the support member 2 extends.

One end of two arm members 3 extending in the X-axis direction is coupled to the other end of the support member 2. The tip member 4 extending in the Z-axis direction is coupled to the other end of each arm member 3. A contact portion 6 is formed at the tip of the tip member 4 in the Z-axis direction. The material of the contact portion 6 is, for example, Rh (rhodium).

The probe 100 inspects the inspected object by bringing the contact portion 6 formed on the tip member 4 into contact with the electrode terminal of the inspected object.

A projection 5A extending in the Z-axis direction is formed on the outer edge portion 4a of the tip member 4. Similarly, a projection 5B extending in the Z-axis direction is formed on the outer edge portion 2a of the support member 2. That is, the projections 5A and 5B are arranged parallel to each other. Moreover, the surfaces (outer surfaces) of the respective projections 5A and 5B are formed in a smooth planar shape. The width t2 of the respective projections 5A and 5B in the Y-axis direction is narrower than the thickness t1 (first plate thickness) of the probe 100. The projections 5A and 5B can be made of, for example, Rh (rhodium), which is the same as the contact portion 6.

FIG. 3 is an explanatory view illustrating the positional relationship between the outer edge portion 2a of the support member 2 and the projection 5B. As illustrated in FIG. 3, the center of the outer edge portion 2a coincides with the center of the projection 5B on the center line CL. Accordingly, space regions Q1 and Q2 are formed on the side surfaces 5B1 and 5B2 of the projection 5B in the Y-axis direction by the respective steps between the projection 5B and the support member 2. By forming the space regions Q1 and Q2, it is possible to avoid interference between the support member 2 and the tip member 4, and the arc-shaped corner portion R1 which will be described later.

The centers of the projections 5A and 5B substantially coincide with the center of the contact portion 6 on the center line in the X-axis direction. The width t2 of the projections 5A and 5B in the Y-axis direction substantially coincides with the width of the contact portion 6 in the Y-axis direction. That is, the center of the contact portion 6 in the thickness direction coincides with the center of the projections 5A and 5B in the thickness direction.

Next, an operation of positioning the probe 100 using a fixing jig for fixing the probe will be described. FIGS. 4A to 4C are explanatory views schematically illustrating a state in which the probe is inserted into the fixing jig, FIG. 4A is a side view, FIG. 4B is an I-I cross-sectional view, and FIG. 4C is a plan view. FIGS. 5A to 5C are explanatory views schematically illustrating a state in which a first guide plate is slid with respect to a second guide plate, FIG. 5A is a side view, FIG. 5B is an II-II cross-sectional view, and FIG. 5C is a plan view.

As illustrated in FIGS. 4A and 4B, the fixing jig has a first guide plate 21 and a second guide plate 22, and the guide plates 21 and 22 are arranged in a stacked manner. Moreover, as illustrated in FIG. 4C in an initial state, the opening 31 formed in the first guide plate 21 and the opening 32 formed in the second guide plate 22 coincide with each other in a plan view (Z-axis direction).

As illustrated in FIG. 4C, the openings 31 and 32 have a rectangular shape, and the four corner portions are formed in an arc shape. The size of the openings 31 and 32 is slightly larger than the cross-sectional area of the probe. Therefore, in the initial state, as illustrated in FIGS. 4A and 4B, the probe 100 can be inserted into the openings 31 and 32 without difficulty.

When positioning the probe 100, the first guide plate 21 is slid with respect to the second guide plate 22 from the states illustrated in FIGS. 4A to 4C. Specifically, when the first guide plate 21 is slid in the X-axis direction, as illustrated in FIG. 5A, the side surface 31a of the opening 31 comes into contact with the projection 5B, and the probe 100 moves in the X-axis direction (rightward direction in FIG. 5A). Therefore, the side surface 32a of the opening 32 comes into contact with the projection 5A. As a result, the probe 100 is constrained in the X-axis direction. That is, the probe 100 can be positioned in the X-axis direction.

Further, by sliding the first guide plate 21 in the Y-axis direction, the side surface 31b of the opening 31 comes into contact with the side surfaces of the support member 2 and the tip member 4 as illustrated in FIG. 5B, and the probe 100 slides in the Y-axis direction (the left direction in FIG. 5A). Therefore, the side surface 32b of the opening 32 comes into contact with the side surfaces of the support member 2 and the tip member 4. As a result, the probe 100 is constrained in the Y-axis direction. That is, the probe 100 can be positioned in the Y-axis direction.

That is, as illustrated in FIG. 5C, the probe 100 can be positioned on the X-Y plane by sliding the opening 31 slightly in the X-axis direction and the Y-axis direction with respect to the opening 32.

Next, the positional relationship among the projection 5B, the support member 2, and the opening 32 will be described with reference to FIGS. 6 and 7. FIG. 6 is an explanatory view illustrating the positional relationship when the probe 101 (comparative example) without the projections 5A and 5B illustrated in FIGS. 1 and 2 is used. As illustrated in FIG. 6, when the probe 101 is slid in the X-axis direction (left direction in the figure), the outer edge portion 2a of the support member 2 and the inner surface 31c of the opening 31 come into surface contact with each other. Further, when the probe 101 is slid in the Y-axis direction (upper direction in the figure) from this state, the corner portion R1 of the opening 31 is formed in an arc shape, so that the side surface 2b of the support member 2 and the corner portion R1 interfere with each other. Therefore, the side surface 2b and the inner surface 31c of the opening 31 cannot be brought into surface contact with each other, and a space S is generated. As a result, the probe 101 cannot be positioned at an accurate position.

FIG. 7 is an explanatory view illustrating the positional relationship when the probe 100 (present embodiment) illustrated in FIGS. 1 and 2 is used. As illustrated in FIG. 7, when the probe 100 is slid in the X-axis direction (left direction in the figure), the projection 5B formed on the outer edge portion 2a of the support member 2 and the inner surface 31c of the opening 31 come into surface contact with each other. Further, since the space regions Q1 and Q2 are formed on the lateral sides of the projection 5B, even when the probe 100 is slid in the Y-axis direction (upper direction in the figure), the interference between the side surface 2b of the support member 2 and the corner portion R1 can be avoided. Therefore, the side surface 2b of the support member 2 and the inner surface 31c of the opening 31 can be brought into surface contact reliably and thus, the probe 100 can be positioned accurately.

Although the relationship between the projection 5B formed on the support member 2 and the openings 31 and 32 has been described in FIG. 7, the same shall apply to the projection 5A formed on the tip member 4. Therefore, even when the corner portions R1 of the openings 31 and 32 are formed in an arc shape, the side surfaces of the support member 2 and the tip member 4 can be brought into contact with the inner surfaces of the openings 31 and 32 reliably.

As described above, the probe 100 according to the present embodiment includes: the foot portion 1 having an elongated shape; the flat plate-shaped support member 2 that is coupled to one end of the foot portion 1, extends in the first direction (Z-axis direction), and has a thickness t1 (first plate thickness); the arm member 3 that has one end c coupled to the support member 2 and extends in the longitudinal direction of the foot portion 1; the flat plate-shaped tip member 4 that is coupled to the other end of the arm member 3, extends in the first direction, and has the first plate thickness; and the contact portion 6 that projects from the tip member 4 in the first direction. The projections 5A and 5B having a width narrower than the first plate thickness in the first direction are formed on the outer edge portion 2a of the support member 2 and the outer edge portion 4a of the tip member 4.

Accordingly, when the probe 100 is restrained by sliding the first guide plate 21, the support member 2 and the tip member 4 of the probe 100 can be reliably brought into surface contact with the inner surfaces of the openings 31 and 32 of the respective guide plates 21 and 22. Therefore, even when the guide plates 21 and 22 with the openings 31 and 32 having arc-shaped corner portions are used, the probe 100 can be accurately positioned.

Further, in the present embodiment, since the material for forming the contact portion 6 and the material for forming the projections 5A and 5B are the same (for example, Rh), the projections 5A and 5B can be formed with a simple method by forming a pattern using photolithography.

In the present embodiment, since the surfaces (the planes that contact the inner surfaces of the openings 31 and 32) of the respective projections 5A and 5B are formed in a smooth planar shape, the respective projections 5A and 5B can be reliably brought into surface contact with the inner surfaces of the respective openings 31 and 32, thereby improving the positioning accuracy of the probe 100.

Further, as illustrated in FIG. 3, in the Y-axis direction, the center of the support member 2 and the center of the projection 5B coincide with each other, and the center of the tip member 4 and the center of the projection 5A coincide with each other. Therefore, the space region Q1 can be secured to similar extents on the left and right sides, thereby further improving the positioning accuracy of the probe 100.

Further, since the centers of the projections 5A and 5B and the center of the contact portion 6 substantially coincide with each other on the center line in the X-axis direction, the stress applied when the contact portion 6 comes into contact with an inspection element can be stably transmitted in the Z-axis direction. For example, in the case where the projections 5A and 5B are formed of a member harder than the base material of the probe 100, if the arrangement of the projections 5A and 5B is deviated from the center axis of the contact portion 6 in the X-axis direction, there is a possibility that the probe 100 is curved in the X-axis direction by the stress applied during the execution of the inspection. Since the centers of the projections 5A and 5B and the center of the contact portion 6 substantially coincide with each other on the center line in the X-axis direction, the deviation of the stress, which is applied to the base material during the contact, in the X-axis direction can be suppressed, thereby suppressing the curvature in the X-axis direction generated during the contact.

In the first embodiment, although the probe having the shape illustrated in FIGS. 1 and 2 has been described as an example, the probe according to the present disclosure is not limited to the shape illustrated in FIGS. 1 and 2. For example, the present disclosure can be applied to probes having three or more arm members 3.

### First modified example

Next, a first modified example will be described. FIG. 8 is a perspective view of a probe 100A according to the first modified example, and FIG. 9 is a side view of the probe 100A. The probe 100A illustrated in FIGS. 8 and 9 differs from the probe 100 illustrated in FIGS. 1 and 2 in that the contact portion 6 and the projection 5A are coupled to each other.

As described above, the contact portion 6 and the projection 5A are made of the same material, for example, Rh. Therefore, the contact portion 6 and the projection 5A can be formed at once by photolithography, thereby reducing labor and cost during manufacture.

### Second modified example

FIG. 10 is a side view of a probe 100B according to a second modified example. In the probe 100B illustrated in FIG. 10, the projection 5A formed on the outer edge portion 4a of the tip member 4 is formed shorter than that of the probe 100 illustrated in FIG. 2. Even in this configuration, as in the first embodiment described above, it is possible to accurately position the probe 100B even when the guide plates 21 and 22 with the openings 31 and 32 having arc-shaped corner portions are used. In addition, it is possible to reduce the material for forming the projection 5A, thereby reducing the cost.

### Third modified example

FIG. 11 is a side view of the probe 100C according to a third modified example. In the probe 100C illustrated in FIG. 11, the projection 5B formed on the outer edge portion 2a of the support member 2 is formed intermittently in comparison with the probe 100 illustrated in FIG. 2. Even in this configuration, as in the first embodiment described above, it is possible to accurately position the probe 100C even when the guide plates 21 and 22 with the openings 31 and 32 having arc-shaped corner portions are used. In addition, it is possible to reduce the material for forming the projection 5B, thereby reducing the cost.

Although the embodiments of the present disclosure have been described, it should not be understood that the statements and drawings which form a part of this disclosure are intended to limit the disclosure. Various alternative embodiments, examples and operating techniques will be apparent to those skilled in the art from this disclosure.

1. A probe comprising:
a foot portion having an elongated shape;
a flat plate-shaped support member that is coupled to one end of the foot portion, extends in a first direction, and has a first plate thickness;
an arm member that has one end coupled to the support member and extends in a longitudinal direction of the foot portion;
a flat plate-shaped tip member that is coupled to the other end of the arm member, extends in the first direction, and has the first plate thickness; and
a contact portion that projects from the tip member in the first direction,
wherein a projection having a width narrower than the first plate thickness in the first direction is formed on an outer edge portion of the support member and an outer edge portion of the tip member.

2. The probe according to claim 1,
wherein a center of the contact portion in a thickness direction coincides with a center of the projection in a thickness direction.

3. The probe according to claim 1,
wherein the projection is made of the same material as the contact portion.

4. The probe according to claim 3,
wherein the projection formed on the tip member is coupled to the contact portion.

5. The probe according to claim 1,
wherein the projection is formed intermittently in the first direction.
